(19) United States
(12) Patent Application Publication
(10) Pub. No.: US 2005/0279281 A1
(43) Pub. Date: Dec. 22, 2005

(54) Substrate processing apparatus

(75) Inventors: Masami Yamashita, Tokyo (JP); Seiji Nakashima, Kumamoto (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/152,210

(22) Filed: Jun. 15, 2005

(30) Foreign Application Priority Data
Jun. 22, 2004 (JP) 2004-183919

(51) Int. Cl. C23C 16/00; C23F 1/00

(52) U.S. Cl. 118/719; 156/345.31

(57) ABSTRACT

An object of the present invention is to improve the operation efficiency of a substrate processing apparatus while ensuring the safety of an operator who performs maintenance of the apparatus. The present invention is a substrate processing apparatus including a substrate unit capable of housing a substrate and a substrate carrier unit for carrying the substrate to the substrate unit, in a casing, including: an outer wall panel detachably attached to the casing at a position opposed to the substrate unit; a shut-off mechanism capable of shutting a first space within which the substrate unit is located off from a second space other than the first space within which the substrate carrier unit is located, in the casing, the first space being opened to the outside of the casing by detaching the outer wall panel; a shut-off mechanism operating member for operating the shut-off mechanism to shut the first space off from the second space; and an interlock mechanism for stopping motion of the whole in the casing when the outer wall panel is detached. The apparatus has an interlock disabling mechanism for disabling the interlock mechanism when the shut-off mechanism shuts the first space off from the second space.

### BACKGROUND OF THE INVENTION

1. Field of the Invention

The present invention relates to a substrate processing apparatus.

2. Description of the Related Art

Photolithography process in a manufacturing process of, for example, a semiconductor device is usually performed using a coating and developing treatment apparatus. In recent years, there has been a proposed coating and developing treatment apparatus in which a loader/unloader section for carrying in/out a substrate to/from a casing, an inspection section for performing various inspections for the substrate; a processing section for performing a plurality of kinds of processing and treatments such as a resist coating treatment, developing treatment, thermal processing, and so on, and an interface section for delivering the substrate to/from the processing section and an aligner, are arranged in series (see Japanese Patent Application Laid-open No. 2002-26107). A plurality of inspection units are arranged in the inspection section, and a plurality of processing and treatment units are arranged in the processing section. Further, in the coating and developing treatment apparatus, a plurality of substrate carrier units each for carrying the substrate between the sections or between the units are provided, for example, in the casing.

Incidentally, when a poor condition occurs in the above-described units in the coating and developing treatment apparatus and its repair or maintenance is performed, an operator detaches an outer wall panel provided on the outer wall of the casing and accesses the unit in the casing through that portion to perform the maintenance. In this event, it is dangerous if the operator inserts his or her hand or face into the casing during operation of the substrate carrier unit. Moreover, an apparatus design that allows an ordinary operator to access the substrate carrier unit in operation is not permitted in terms of safety standards of the coating and developing treatment apparatus.

To ensure the safety of the operator and to meet the safety standards of the apparatus, an interlock mechanism has conventionally been provided in the coating and developing treatment apparatus, which stops all of the motions of the units existing in the casing when the outer wall panel is detached, by shutting down the power supply of the whole in the casing. Accordingly, the coating and developing treatment apparatus has been configured such that when the operator detaches the outer wall panel for maintenance, all of the substrate carrier units, the processing units, and the inspection units are forcibly stopped.

However, if the motion of the whole apparatus is stopped, for example, while a plurality of substrates are under processing in the coating and developing treatment apparatus, all of the substrates under processing existing in the apparatus can result in defectives. For this reason, if any poor condition occurs during the operation of the coating and developing treatment apparatus, conventionally, the operator has waited until after all of the plurality of substrates in the coating and developing treatment apparatus proceed through processing and are returned to the loader/unloader section, and then has detached the outer wall panel to perform maintenance in the apparatus. This has required waiting time and maintenance time until after the substrates are returned into the loader/unloader section every time maintenance is performed because of occurrence of a poor condition in the coating and developing treatment apparatus.

Further, even a breakage of only a portion in the coating and developing treatment apparatus has also required stop of the whole apparatus to perform maintenance, thus decreasing the operation rate of the apparatus to result in a significantly lowered manufacturing efficiency of substrates. In particular, in the coating and developing treatment apparatus incorporating the above-described inspection units, poor conditions associated with the inspection unit are apt to occur and require a larger number of times of maintenance, leading to a significant decrease in manufacturing efficiency. Some coating and developing treatment apparatuses include a release key for the interlock mechanism, and persons who can release the interlock mechanism and access the inside of the apparatus are limited to those having a predetermined qualification according to rules in place. Therefore, when an ordinary operator performs maintenance, the operator can only stop the whole apparatus to perform maintenance.

As has been described, in the conventional coating and developing treatment apparatus, the safety of the operator during maintenance has been ensured, whereas much recovery time has been required due to the poor condition in the apparatus to result in a decrease in the operation efficiency of the apparatus.

### SUMMARY OF THE INVENTION

The present invention has been developed in consideration of the above points, and its object is to provide a substrate processing apparatus capable of increasing the operation efficiency of the apparatus while ensuring the safety of an operator who performs maintenance.

To attain the above-described object, the present invention is a substrate processing apparatus including a substrate unit capable of housing a substrate and a substrate carrier unit for carrying the substrate to the substrate unit, in a casing, including: an outer wall panel detachably attached to the casing at a position opposed to the substrate unit; a shut-off mechanism capable of shutting a first space within which the substrate unit is located off from a second space other than the first space within which the substrate carrier unit is located, in the casing, the first space being opened to the outside of the casing by detaching the outer wall panel; a shut-off mechanism operating member for operating the shut-off mechanism to shut the first space off from the second space; an interlock mechanism for stopping motion of the whole apparatus in the casing including the substrate carrier unit when the outer wall panel is detached; and an interlock disabling mechanism for disabling the interlock mechanism when the shut-off mechanism shuts the first space off from the second space.

According to the present invention, in the event of occurrence of a poor condition, for example, in the substrate unit in the casing, the shut-off mechanism operating member can operate the shut-off mechanism to shut the first space where the substrate unit exists off from the second space in the casing. Accordingly, when the operator detaches the outer wall panel, the first space where the substrate unit exists is shut off from the remaining second space where the substrate carrier unit exists, so that the safety of the operator is ensured even if the substrate carrier unit is operating. At this time, the operator is not allowed to access the substrate carrier unit in operation, whereby the safety standards of the apparatus can also be met. On the other hand, when the first space is shut off from the second space, the interlock mechanism becomes disabled, so that the outer panel can be detached to perform maintenance of the substrate unit with, for example, the substrate carrier unit within the second space carrier unit being operating. Accordingly, the other operation in the casing can be continued, while maintenance is being performed, for example, for the substrate unit. As a result of this, the operation rate of the substrate processing apparatus can be improved.

Further, according to another aspect of the present invention, the present invention is a substrate processing apparatus including a substrate unit capable of housing a substrate and a substrate carrier unit for carrying the substrate to the substrate unit, in a casing, including: a substrate carrier path between the substrate carrier unit and the substrate unit; an opening portion formed in a wall surface of the casing on a side opposite to the substrate carrier path across from the substrate unit; a shutter capable of opening/shutting the substrate carrier path and the opening portion to shut the substrate carrier path at least before opening the opening portion; an interlock mechanism for stopping motion of the apparatus in the casing including the substrate carrier unit when the opening portion is opened; and an interlock disabling mechanism for disabling the interlock mechanism when the shutter shuts the substrate carrier path.

According to the present invention, when a poor condition occurs, for example, in the substrate unit in the casing, the shutter opens the opening portion of the casing to allow the operator to perform work for the substrate carrier unit. In this event, the substrate carrier unit cannot access the substrate unit because the casing on the substrate carrier path side between the substrate unit and the substrate carrier unit is shut. Accordingly, the safety of the operator when performing maintenance of the substrate unit can be ensured. Further, since the operator cannot access the substrate carrier unit in operation, the safety standards of the apparatus can also be met. On the other hand, when the shutter shuts the substrate carrier path, the interlock mechanism becomes disabled, so that the operator can perform maintenance of the substrate unit with, for example, the substrate carrier unit being operating. Accordingly, the other operation in the casing can be continued, while maintenance is being performed, for example, for the substrate unit. As a result of this, the operation rate of the substrate processing apparatus can be improved.

According to the present invention, it is possible to improve the operation efficiency of the substrate processing apparatus while ensuring the safety of the operator who performs maintenance for the substrate processing apparatus.

### BRIEF DESCRIPTION OF THE DRAWINGS

FIG. 1 is a perspective view showing the outline of a coating and developing treatment apparatus according to the embodiment;

FIG. 2 is an explanatory view of a cross section showing the outline of the configuration of the coating and developing treatment apparatus;

FIG. 3 is a front view of the coating and developing treatment apparatus of FIG. 2;

FIG. 4 is a rear view of the coating and developing treatment apparatus of FIG. 2;

FIG. 5 is an explanatory view showing a configuration of a partition plate;

FIG. 6 is an explanatory view showing an outer wall panel provided with a handle;

FIG. 7 is an explanatory view of a longitudinal section showing a configuration of the inside of an inspection station when a second space is partitioned into two tiers, an upper one and a lower one;

FIG. 8 is an explanatory view of a cross section showing the configuration of the inside of the inspection station in which an X-Y stage and a rotary table are provided;

FIG. 9 is an explanatory view of a cross section of the inspection station showing a state in which a housing is rotated;

FIG. 10 is an explanatory view of a cross section showing the inside of the inspection station in which a sliding shutter is provided;

FIG. 11 is an explanatory view of a cross section of the inspection station showing a state in which both of a wafer carrier path and an opening portion are shut; and

FIG. 12 is an explanatory view of a cross section of the inspection station showing a state in which the opening portion is opened.

### DETAILED DESCRIPTION OF THE PREFERRED EMBODIMENT

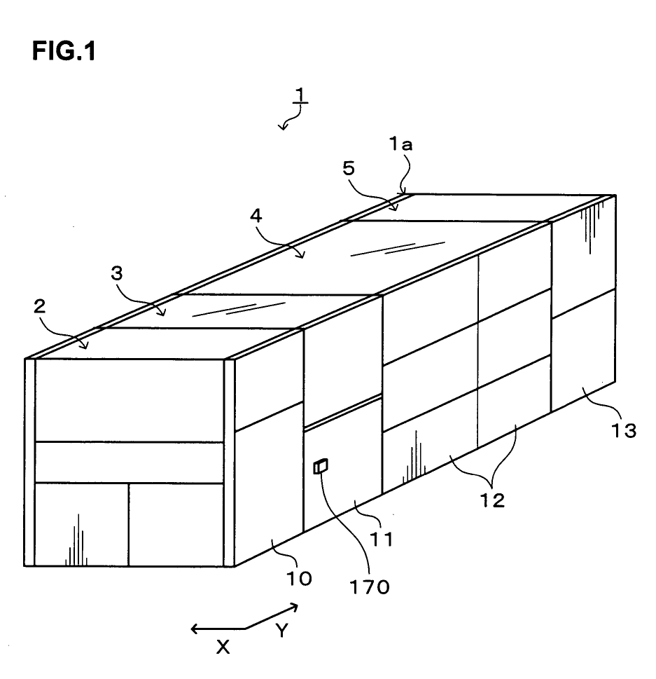

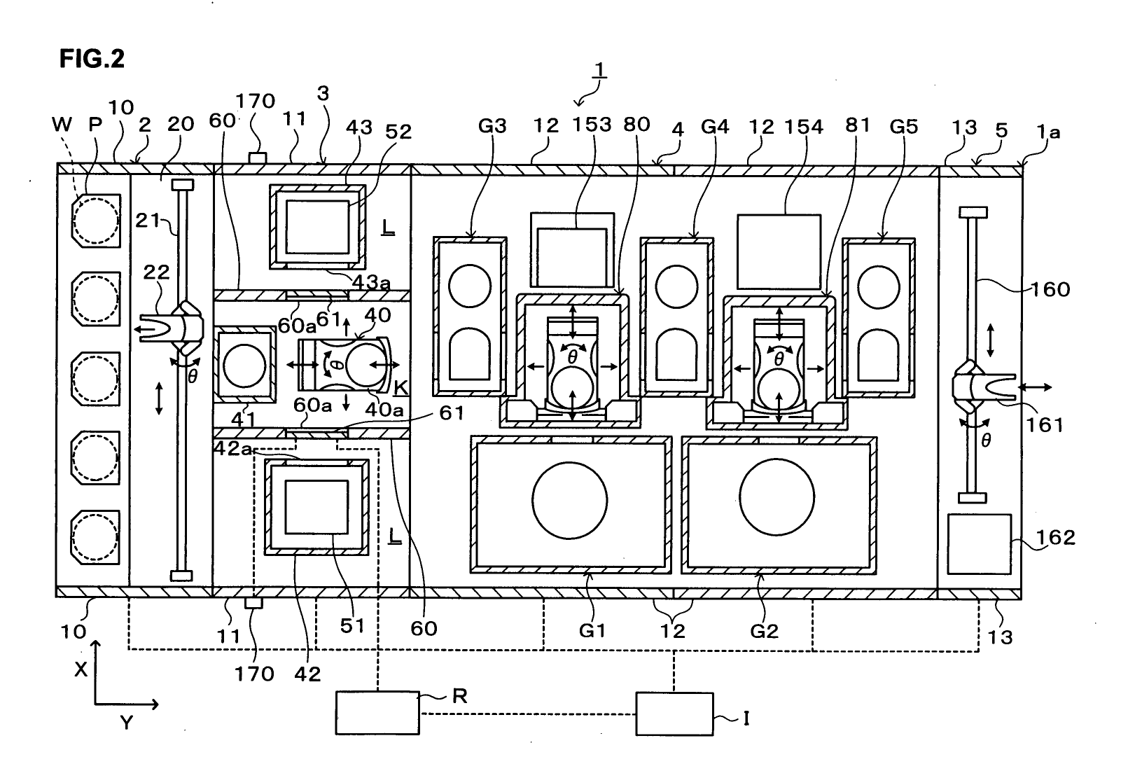

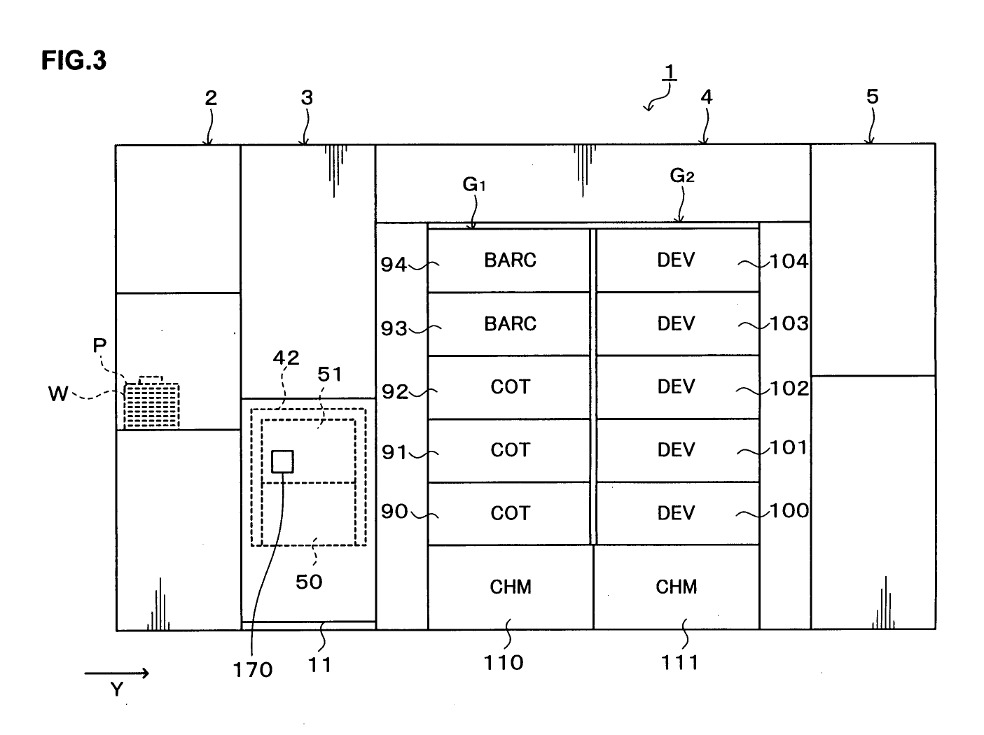

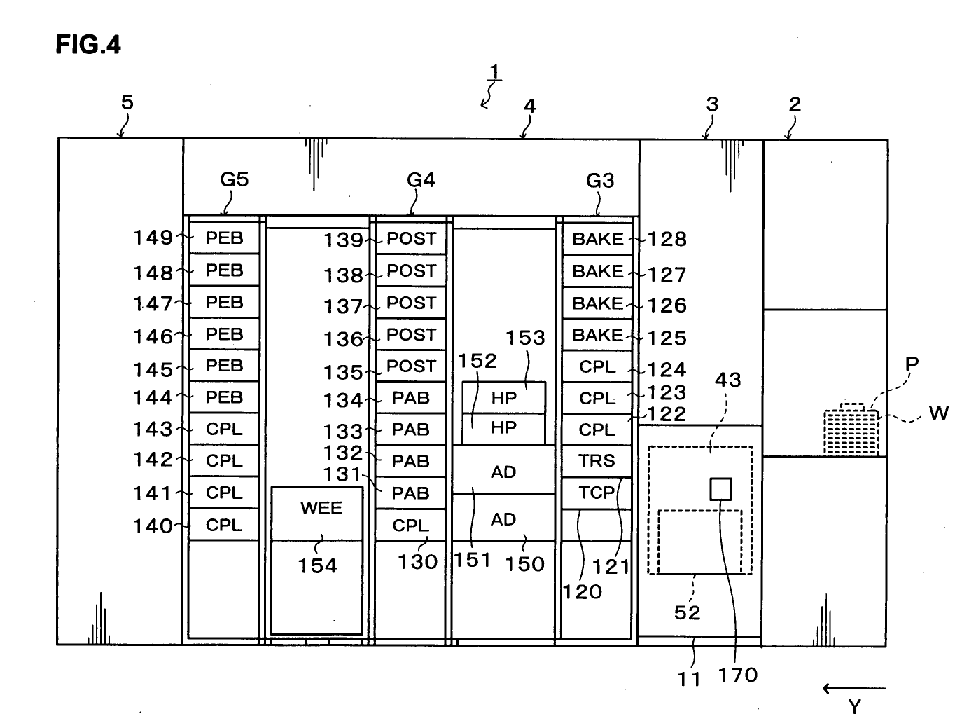

Hereinafter, a preferred embodiment of the present invention will be described. FIG. 1 is a perspective view showing the outline of a configuration of a coating and developing treatment apparatus 1 as a substrate processing apparatus according to the embodiment, FIG. 2 is an explanatory view of a cross section showing the outline of the configuration of the coating and developing treatment apparatus 1, FIG. 3 is a front view of the coating and developing treatment apparatus 1, and FIG. 4 is a rear view of the coating and developing treatment apparatus 1.

The coating and developing treatment apparatus 1 is entirely covered by a casing 1a being an outer wall so that the inside of the coating and developing treatment apparatus 1 is enclosed as shown in FIG. 1. Inside the casing 1a of the coating and developing treatment apparatus 1, for example, a cassette station 2 as a carry-in/out section for carrying, for example, 25 wafers W per cassette, as a unit of cassette P, from/to the outside into/out of the coating and developing treatment apparatus 1 and carrying the wafers W into/out of the cassette P, an inspection station 3 as an inspection section for inspecting the wafers W, a processing station 4 as a processing section including various kinds of processing and treatment units, which are multi-tiered, for performing predetermined processing or treatments in a manner of single wafer processing in coating and developing treatment processes, and an interface section 5 for delivering the wafers W to/from a not-shown aligner provided adjacent to the processing station 4, are provided side by side in separated blocks in series. Outer wall panels 10, 11, 12, and 13 for maintenance of the inside of the blocks are provided respectively on the side walls of the casing 1a in the blocks of the cassette station 2, the inspection station 3, the processing station 4, and the interface section 5. The outer wall panels 10 to 13 are attached to the casing 1a with, for example, magnets so as to be detachable.

In the cassette station 2, a plurality of cassettes P can be mounted at predetermined positions on a cassette mounting table 20 as shown in FIG. 2 in a line in an X-direction (a top-to-bottom direction in FIG. 2). In the cassette station 2, a wafer carrier unit 22 is provided which is movable in the X-direction on a carrier path 21. The wafer carrier unit 22 is movable also in the vertical direction and thus can selectively access the wafers W arranged in the vertical direction in the cassette P. The wafer carrier unit 22 is rotatable around an axis in the vertical direction (a θ-direction) and thus can also access a later-described transfer unit 41 on the inspection station 3 side.

A wafer carrier unit 40 as a substrate carrier unit is provided at the central portion of the inspection station 3 adjacent to the cassette station 2 as shown in FIG. 2. The wafer carrier unit 40 has a carrier arm 40a which, for example, freely move back and forth so that it can carry the wafer W held on the carrier arm 40a. The carrier arm 40a can rotate in the θ-direction so that it can carry the wafer W in a predetermined direction. The carrier arm 40a can move also in the vertical direction so that it can be adjusted in height.

On the cassette station 2 side of the wafer carrier unit 40, for example, the transfer unit 41 is provided. The wafer carrier unit 40 can access the transfer unit 41 and carry the wafer W to the cassette station 2 side via the transfer unit 41. The wafer carrier unit 40 can also carry the wafer W directly to a later-described third processing unit group G3 in the processing station 4.

Housings 42 and 43 each in an almost rectangle parallelpiped shape for housing predetermined inspection units are provided on both sides in the X-direction of the wafer carrier unit 40 and near the outer wall panel 11. For example, in the first housing 42 on the front side (on the side of the lower direction in FIG. 2; the negative direction in the X-direction) of the inspection station 3, inspection units as substrate units, for example, a film thickness and line width inspection unit 50 for measuring the thickness of a film formed on the wafer W and the line width of a pattern thereof, and a macrodefect inspection unit 51 for detecting macrodefects on the wafer surface are housed in two tiers in order from the bottom, for example, as shown in FIG. 3. In the second housing 43 on the rear side (on the side of the upper direction in FIG. 2; the positive direction in the X-direction) of the inspection station 3, an overlay inspection unit 52 for detecting misalignment in overlay in exposure is housed as shown in FIG. 4. In the wall surfaces on the wafer carrier unit 40 side in the housings 42 and 43, carrier ports 42a and 43a for allowing the wafer W to be carried therethrough are formed for the units respectively as shown in FIG. 2.

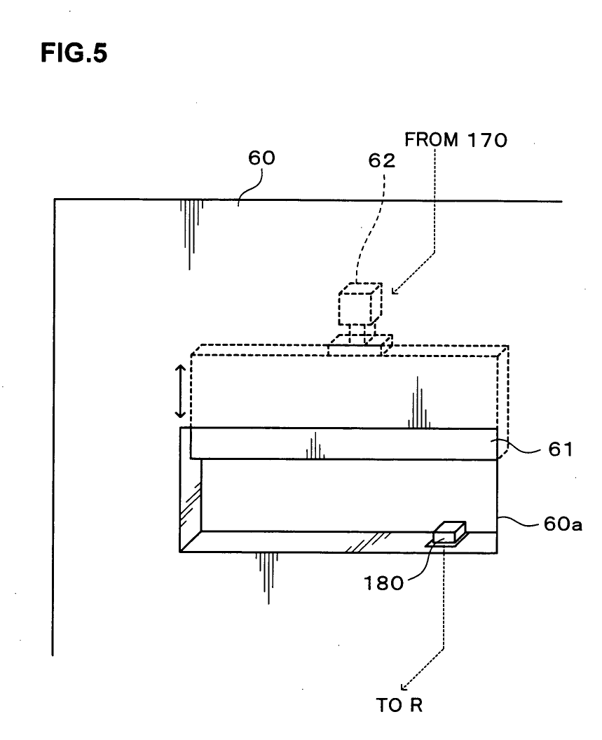

Between the wafer carrier unit 40 and the first housing 42, a partition plate 60 is provided which partitions the inspection station 3 into a first space L on the first housing 42 side and a second space K on the wafer carrier unit 0.40 side as shown in FIG. 2. A carry-in/out port 60a is formed in the partition plate 60 at a position opposed to the carrier port 42a of the first housing 42. A shutter 61 is provided on the carry-in/out port 60a. The shutter 61 can be raised and lowered, for example, by a cylinder 62 as a shutter driving portion as shown in FIG. 5 to open/shut the carry-in/out port 60a. This can physically shut the first space L on the first housing 42 side off from the second space K on the wafer carrier unit 40 side. Note that the shutter 61 and the cylinder 62 form a shut-off mechanism in this embodiment.

On the second housing 43 side, similarly to the first housing 42 side, between the wafer carrier unit 40 and the second housing 43, a partition plate 60 which partitions the second space K from a first space L on the second housing 43 side is also provided as shown in FIG. 2. A carry-in/out port 60a is formed in the partition plate 60 at a position opposed to the carrier port 43a of the second housing 43. A shutter 61 raised and lowered by a cylinder 62 is provided on the carry-in/out port 60a. The shutter 61 can shut the first space L on the second housing 43 side off from the second space K on the wafer carrier unit 40 side.

The wafer carrier unit 40 can carry the wafer W to the inspection units 50 to 52 via the carry-in/out port 60a with the shutter 61 open and the carrier port 42a or the carrier port 43a. As described above, the wafer carrier unit 40 can carry the wafer W between the inspection units 50 to 52, the third processing unit group G3, and the transfer unit 41.

The processing station 4 adjacent to the inspection station 3 comprises, for example, five processing unit groups G1 to G5 in each of which a plurality of processing and treatment units are multi-tiered as shown in FIG. 2. On the side of the negative direction in the X-direction in the processing station 4, the first processing unit group G1 and the second processing unit group G2 are placed in order from the inspection station 3 side. On the side of the positive direction in the X-direction in the processing station 4, the third processing unit group G3, the fourth processing unit group G4, and the fifth processing unit group G5 are placed in order from the inspection station 3 side. Between the third processing unit group G3 and the fourth processing unit group G4, a first wafer carrier unit 80 is provided. The first wafer carrier unit 80 can carry the wafer W to the processing and treatment units in the first processing unit group G1, the third processing unit group G3, and the forth processing unit group G4. Between the fourth processing unit group G4 and the fifth processing unit group G5, a second wafer carrier unit 81 is provided. The second wafer carrier unit 81 can carry the wafer W to the processing and treatment units in the second processing unit group G2, the fourth processing unit group G4, and the fifth processing unit group G5.

As shown in FIG. 3, in the first processing unit group G1, solution treatment units each for supplying a predetermined solution onto the wafer W to thereby perform treatment, for example, resist coating units 90, 91, and 92 each for applying a resist solution onto the wafer W, and bottom coating units 93 and 94 each for forming an anti-reflection film which prevents reflection of light during exposure processing, are five-tiered in order from the bottom. In the second processing unit group G2, solution treatment units, for example, developing treatment units 100 to 104 each for developing the wafer W are five-tiered in order from the bottom. Further, chemical chambers 110 and 111 each for supplying various kinds of treatment solutions to the solution treatment units in the processing unit groups G1 and G2 are provided at the lowermost tiers of the first processing unit group G1 and the second processing unit group G2, respectively.

As shown in FIG. 4, in the third processing unit group G3, for example, a temperature regulating unit 120, a transition unit 121 for passing the wafer W, high-precision temperature regulating units 122 to 124 each for heating the wafer W under temperature control with a high precision, and high-temperature thermal processing units 125 to 128 each for heating the wafer W at a high temperature, are nine-tiered in order from the bottom.

In the fourth processing unit group G4, for example, a high-precision temperature regulating unit 130, pre-baking units 131 to 134 each for heating the wafer W after the resist coating treatment, and post-baking units 135 to 139 each for heating the wafer W after the developing treatment are ten-tiered in order from the bottom.

In the fifth processing unit group G5, a plurality of thermal processing units each for thermally processing the wafer W, for example, high-precision temperature regulating unit 140 to 143, and post-exposure baking units 144 to 149 each for heating the wafer W after the exposure, are ten-tiered in order form the bottom.

As shown in FIG. 2, on the side of the positive direction in the X-direction of the first wafer carrier unit 80, a plurality of processing units are arranged, for example, adhesion units 150 and 151 each for performing hydrophobic treatment on the wafer W and heating processing units 152 and 153 each for heating the wafer W being four-tiered in order from the bottom as shown in FIG. 4. As shown in FIG. 2, on the side of the positive direction in the X-direction of the second carrier unit 81, for example, an edge exposure unit 154 for selectively exposing only the edge portion of the wafer W is located.

In the interface section 5, as shown in FIG. 2, for example, a wafer carrier unit 161 moving on a carrier path 160 extending in the X-direction and a buffer cassette 162 are provided. The wafer carrier unit 161 is movable in a Z-direction and also rotatable in the θ-direction and thus can access the not-shown aligner adjacent to the interface section 5, the buffer cassette 162, and the processing unit group G5 to carry the wafer W to them.

In the coating and developing treatment apparatus 1, an interlock mechanism I is provided which forcibly stops all the motions in the casing 1a, including those of, for example, the wafer carrier units 22, 40, 80, 81, and 161, when any one of the outer wall panels 10 to 13 is detached. Because of detachment of any of the outer wall panels 10 to 13, the interlock mechanism I opens, for example, a circuit, which passes electric current when the outer wall panels 10 to 13 are attached to the casing 1a, so that the opening stops feeding of current to the inside of the casing 1a to thereby stop the motions in the casing 1a. The interlock mechanism I ensures safety of an operator who performs maintenance of the coating and developing treatment apparatus 1.

For example, the outer wall panel 11 of the inspection station 3 in the coating and developing treatment apparatus 1 is provided with a switch member 170 as a shut-off mechanism operating member for operating the shutter 61 as shown in FIG. 1 and FIG. 2. The switch member 170 is electrically connected, for example, to the cylinder 62, so that a press of the switch member 170 causes current to be fed to the cylinder 62 to operate the shutter 61.

For example, a confirmation button 180 as a shut-off confirmation member, which is automatically pressed when the shutter 61 is lowered, is attached to the carry-in/out port 60a of the partition plate 60 as shown in FIG. 5. The confirmation button 180 is connected to an interlock disabling mechanism R (shown in FIG. 2) which disables the interlock mechanism I, for example, for the outer wall panel 11 of the inspection station 3. The interlock disabling mechanism R forms, for example, a specific circuit coupling to the interlock mechanism I when the confirmation button 180 is pressed so that operation of the specific circuit can disable the interlock mechanism I. Accordingly, even if the outer wall panel 11 is detached after the switch member 170 is pressed to shut the shutter 61, the interlock mechanism I has become disabled in which operations of drive mechanisms including the wafer carrier unit 40 are continued within the region in the casing 1a other than the first space L which is opened by the detachment of the outer wall panel 11.

Control of carriage of the wafer W in the coating and developing treatment apparatus 1 is set to allow flows to be independently performed for each wafer, the flows being, for example, a flow in which the wafer W, which has been processed in the processing station 4, is inspected in the inspection station 3 and then returned to the cassette station 2; a flow in which the wafer W, which has been processed in the processing station 4, is allowed to pass the inspection station 3 without inspection and returned to the cassette station 2; and a flow in which the wafer W in the cassette station 2 is inspected in the inspection station 3 and then returned to the cassette station 2.

In the coating and developing treatment apparatus 1 thus configured, one wafer W in the cassette P on the cassette mounting table 20 is first taken out by the wafer carrier unit 22 and delivered to the transfer unit 41 of the inspection station 3 as shown in FIG. 2. The wafer W delivered to the transfer unit 41 is carried by the wafer carrier unit 40 to the temperature regulating unit 120 included in the third processing unit group G3 in the processing station 4. The wafer W carried to the temperature regulating unit 120 is regulated in temperature and then carried by the first wafer carrier unit 80, for example, to the bottom coating unit 93 where an anti-reflection film is formed thereon, and further carried in sequence to the heating processing unit 152, the high-temperature thermal processing unit 125, and the high-precision temperature regulating unit 130, in each of which the wafer W is subjected to predetermined processing. Thereafter, the wafer W is carried by the first wafer carrier unit 80 to the resist coating unit 90 where the wafer W is subjected to resist coating treatment.

After the finish of the resist coating treatment, the wafer W is carried by the first wafer carrier unit 80 to the pre-baking unit 131 in which it is subjected to heating processing, and then carried by the second wafer carrier unit 81 in sequence to the edge exposure unit 154 and the high-precision temperature regulating unit 143, in each of which the wafer W is subjected to predetermined processing. Thereafter, the wafer W is carried by the wafer carrier unit 161 via the interface section 5 to the not-shown aligner in which a predetermined pattern is exposed on the resist film. The wafer W for which the exposure processing has been finished is returned via the interface section 5 again into the processing station 4, and carried by the second wafer carrier unit 81 in sequence to the post-exposure baking unit 144 and the high-precision temperature regulating unit 141, in each of which the wafer W is subjected to predetermined processing, and then the wafer W is carried into the developing treatment unit 100 and subjected to a developing treatment.

The wafer W for which the developing treatment has been finished is carried by the second wafer carrier unit 81 to the post-baking unit 135 and subjected to heating processing, and then carried by the first wafer carrier unit 80 to the high-precision temperature regulating unit 122 and subjected to cooling processing. Thereafter, the wafer W is carried by the first wafer carrier unit 80 to the transition unit 120. The wafer W carried to the transition unit 120 is carried by the wafer carrier unit 40 in sequence to the film thickness and line width inspection unit 50 and the macrodefect inspection unit 51 in the first housing 42 of the inspection station 3, in each of which the wafer W is subjected to predetermined inspection or measurement. The wafer W is then carried by the wafer carrier unit 40 to the overlay inspection unit 52 in the second housing 43 in which misalignment in overlay is inspected.

The wafer for which the inspection has been finished in the inspection station 3 is delivered by the wafer carrier unit 40 to the transfer unit 41 and returned from the transfer unit 41 by the wafer carrier unit 22 to the cassette P, with which a series of wafer processing in the coating and developing treatment apparatus 1 comes to an end.

Next, the action of the coating and developing treatment apparatus 1 when maintenance is performed to the inspection units in the inspection station 3 in the coating and developing treatment apparatus 1 configured as described above will be described.

In normal operation of the coating and developing treatment apparatus 1 as in the processing of the wafer W, the interlock mechanism I is enabled. Accordingly, when any of the outer wall panels 10 to 13 is detached, the power supply of the whole coating and developing treatment apparatus 1 is shut down to stop all the motions. Then, if the film thickness and line width inspection unit 50 emergently stops because of occurrence of a poor condition in the film thickness and line width inspection unit 50 and the operator performs maintenance to the film thickness and line width inspection unit 50, the operator first presses the switch member 170 on the outer wall panel 11. The press of the switch member 170 feeds current to the cylinder 62 to operate the shutter 61. This causes the shutter 61 to lower to thereby shut the carry-in/out port 60a, thus shutting the first space L within which the film thickness and line width inspection unit 50 exists off from the other second space K within which the wafer carrier unit 40 exists.

When the shutter 61 lowers and the confirmation button 180 is pressed, the interlock disabling mechanism R automatically disables the interlock mechanism I for the outer wall panel 11. The operator presses the switch member 170, then detaches the outer wall panel 11, and performs maintenance of the film thickness and line width inspection unit 50 in the first space L. During the maintenance, the interlock mechanism I is disabled within a region other than the first space L, that is, the cassette station 2, the processing station 4, the interface section 5, and the second space K of the inspection station 3, so that motions of drive mechanisms such as those of the wafer carrier units and processing and treatment units are continued.

For example, the wafer W under processing in the processing station 3 is continuously processed without interruption and, after processing, returned to the cassette station 2 by the wafer carrier unit 40 via the inspection station 3. The unprocessed wafer W in the cassette station 2 is carried by the wafer carrier unit 40 to the processing station 4 side, and subjected to normal wafer processing and then returned to the cassette station 2. Incidentally, maintenance can be similarly performed also when a poor condition occurs in the macrodefect inspection unit 51 or in the overlay inspection unit 52.

According to the above embodiment, a press of the switch members 170 in the inspection station 3 can cause the shutters 61 of the partition plates 60 to shut to completely shut the first spaces L within which the inspection units 50 to 52 exist off from the second space K within which the wafer carrier unit 40 exists, ensuring safety of the operator who accesses the inspection units 50 to 52. In addition, the operator is not allowed to access the wafer carrier unit 40 in operation, thus also meeting the safety standards of the apparatus.

Since the interlock mechanism I for the outer wall panels 11 to open the first spaces L automatically becomes disabled when the shutters 61 are shut to shut the first spaces L on the inspection unit 50 to 52 side off from the second space K on the wafer carrier unit 40 side, the carriage of the wafer and wafer processing in the coating and developing treatment processing apparatus 1 can be continued even if the operator detaches the outer wall panels 11. Accordingly, the motion in the coating and developing treatment apparatus 1 can be continued when maintenance is performed for the inspection units 50 to 52, thus raising operation rates of the coating and developing treatment apparatus 1.

Since the switch member 170 in electrical cooperation with the shutter 61 is provided on the outer wall panel 11, the shutter 61 can lower by a press of the switch member 170 by the operator before detachment of the outer wall panel 11 to surely shut the first space L where maintenance is performed off from the other space. In particular, electrical cooperation of the shutter 61 with the switch member 170 without intervention of software can eliminate malfunction of the shutter 61 to ensure the safety of the operator.

The confirmation button 180 is provided on the carry-in/out port 60a of the partition plate 60 so that the interlock mechanism I becomes disabled only when the shutter 61 actually lowers, thus eliminating a situation in which the outer wall panel 11 is detached by the operator with the wafer carrier unit 40 operating and the shutter 61 open, resulting in securement of sufficient safety of the operator.

The interlock mechanism I for the outer wall panels 11 to access to the inspection units 50 to 52 is designed to become disabled, so that even when the inspection units 50 to 52 which need maintenance a relatively large number of times are incorporated in the coating and developing treatment apparatus 1, a decrease in operation rate of the coating and developing treatment apparatus 1 due to the maintenance can be restrained.

The wafer carrier unit 40 of the inspection station 3 can carry the wafer W between the cassette station 2 and the processing station 4 which are adjacent thereto, so that, for example, it can return the wafer W existing on the processing station 4 side to the cassette station 2 or carry the wafer W in the cassette station 2 to the processing station 4 side during maintenance of the inspection units 50 to 52. This allows, for example, normal wafer processing to be continued in the coating and developing treatment apparatus 1 even during the maintenance of the inspection units 50 to 52.

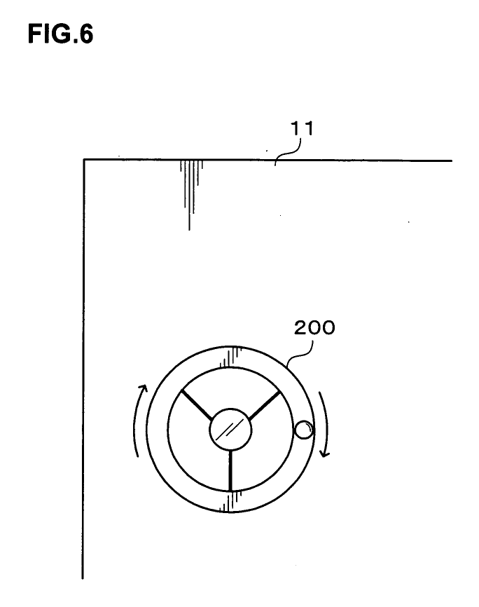

Although the outer wall panel 11 is provided with the switch member 170 for electrically operating the shutter 61 in the above embodiment, a member for mechanically operating the shutter 61, for example, a handle 200 as shown in FIG. 6 may be provided. In this case, the operator rotates the handle 200 in a predetermined direction to shut the shutter 61 via, for example, a not-shown cooperative mechanism. The shutter 61 is opened/shut not using software, thus eliminating malfunction of the shutter 61 to ensue safety of the operator also in this case. Note that a member for mechanically operating the shutter 61 is not limited to the handle 200. For example, when a latch is provided at the outer wall panel 11, the shutter 61 may be operated by engagement/disengagement of the latch.

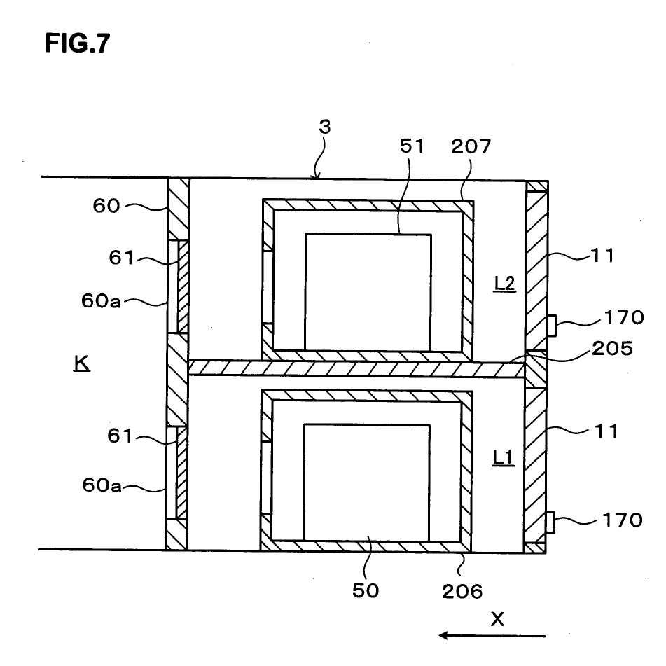

While the two inspection units 50 and 51 are housed in the housing 42 in the above-described embodiment, they may be configured such that the second space L is partitioned, for example, into two upper and lower tiers, that is, a third space L 1 and a fourth space L2 by a horizontal partition plate 205 as shown in FIG. 7, housings 206 and 207 are arranged in the spaces L1 and L2 respectively, the inspection unit 50 is housed in the housing 206 in the third space L1, and the inspection unit 51 is housed in the housing 207 in the fourth space L2. In this case, for example, the outer wall panel 11 is formed for each of the spaces L1 and L2, and the carry-in/out port 60a of the partition plate 60 is formed for each of the spaces L1 and L2. On each of the outer wall panels 11, a switch member 170 is provided similarly to the above-described embodiment, and a shut-off mechanism composed of a shutter 61 and a cylinder 62 and a confirmation button 180 are provided at each of the carry-in/out ports 60a.

In performing maintenance of, for example, the inspection unit 50 in the housing 206, a press of the switch member 170 on the third space L1 side shuts only the carry-in/out port 60a on the third space L1 side to disable the interlock mechanism I only for the outer wall panel 11 on the third space L1 side. This allows the operator to detach the outer wall panel 11 on the third space L1 side and perform maintenance of the inspection unit 50. In this event, since the carry-in/out port 60a on the fourth space L2 side is open, the wafer carrier unit 40 can carry the wafer W to the inspection unit 51 where inspection can be continued. It should be noted that while the second space L is partitioned into two, upper and lower tiers in this example, it is also suitable that when, for example, three or more inspection units are provided, the second space L is partitioned into the number of inspection units, and a housing which houses an inspection unit therein is located in each of the spaces so that maintenance can be performed independently for each inspection unit.

While the shutter 61 of the partition plate 60 shuts the carry-in/out port 60a to shut the first space L on the inspection unit side off from the second space K on the wafer carrier unit 40 side in the above embodiment, the housings 42 and 43 housing the inspection units 50 to 52 may be moved to deviate the carrier ports 42a and 43a from the carry-in/out ports 60a of the partition plates 60 so that the wall surfaces of the housings 42 and 43 shut the carry-in/out ports 60a.

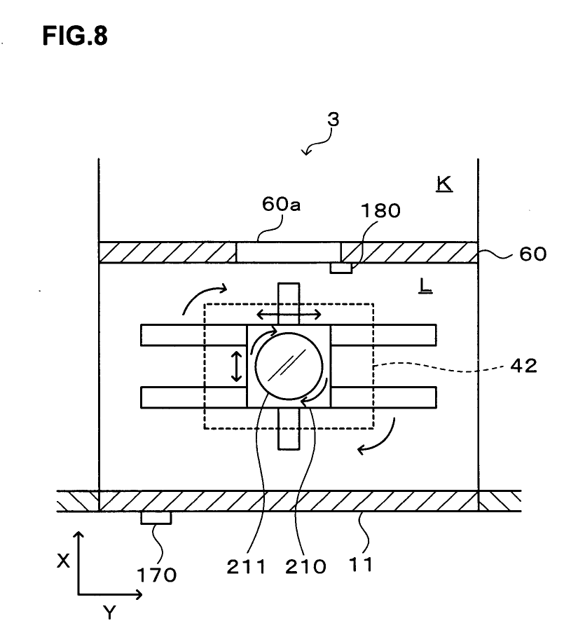

In this case, an X-Y stage 210 horizontally moving in an X-direction and a Y-direction is provided in the first space L of the inspection station 3, for example, as shown in FIG. 8. For example, a rotary table 211 as a rotation device rotating about the vertical axis is provided on the X-Y stage 210. Further, for example, the first housing 42 is provided on the rotary table 211. This allows the first housing 42 to freely move in the X-direction and the Y-direction and rotate in a θ-direction in the first space L.

The X-Y stage 210 and the rotary table 211 electrically cooperate with, for example, the switch member 170 so that a press of the switch member 170 causes the X-Y stage 210 to move to a predetermined position within the X-Y plane and the rotary table 211 to rotate a predetermined angle. Accordingly, upon a press of the switch member 170, the first housing 42 can automatically move to a predetermined position where the wall surface of the first housing 42 shuts the carry-in/out port 60a. Note that an X-Y stage 210 and a rotary table 211 are provided for the second housing 43, so that upon a press of the switch member 170, the second housing 43 can move to a predetermined position to shut the carry-in/out port 60a. In this embodiment, the X-Y stage 210 and the rotary table 211 constitute a housing moving device. Further, the X-Y stage 210, the rotary table 211, and the housing 42 or 43 constitute the shut-off mechanism.

Further, a confirmation button 180, which is pressed when the wall surface of the housing 42 or 43 shuts the carry-in/out port 60a, is provided on the wall surface of the first space L side of the partition plate 60. A press of the confirmation button 180 by the wall surface of the housing 42 or 43 allows the interlock disabling mechanism R to disable the interlock mechanism I for the outer wall panel 11.

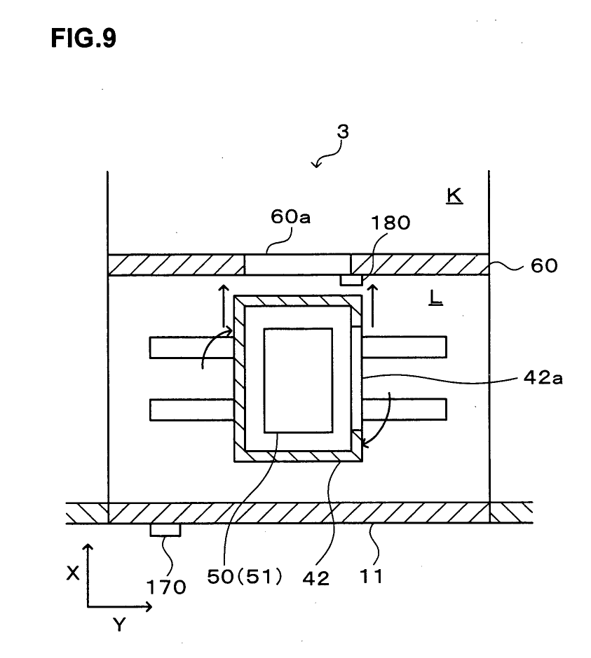

To perform maintenance of the inspection unit 50 or 51 in the first housing 42, a press of the switch member 170 by the operator causes the X-Y stage 210 and the rotary table 211, which are electrically connected to the switch member 170, to operate to move the first housing 42 such that the wall surface of the first housing 42 shuts the carry-in/out port 60a. For example, the first housing 42 rotates 90° to direct the side wall surface having no carrier port 42a to the carry-in/out port 60a side as shown in FIG. 9. Then, the first housing 42 moves toward the positive direction in the X-direction, that is, toward the carry-in/out port 60a to bring the side wall surface of the first housing 42 into close contact with the carry-in/out port 60a. This shuts the carry-in/out port 60a to shut the first space L off from the second space K. The side wall surface of the first housing 42 presses the confirmation button 180 to disable the interlock mechanism I. Then, the operator detaches the outer wall panel 11 and performs maintenance of the inspection unit 50 or 51 in the first housing 42.

Also in this example, a press of the switch members 170 shuts the first spaces L off from the second space K, so that maintenance of the inspection units 50 to 52 can be performed with safety of the operator ensured. Further, the interlock mechanism I becomes disabled after the first spaces L is shut off from the second space K, thus allowing the wafer processing and wafer carriage to be continued within a region other than the inspection units 50 to 52 where maintenance is being performed.

While the side wall surfaces of the housings 42 and 43 shut the carry-in/out ports 60a in the above-described example, wall surfaces of other portions of the housings 42 and 43 may shut the carry-in/out ports 60a. For example, the carry-in/out port 60a may be shut by the wall surface on the rear side of the carrier port 42a in the first housing 42 or the wall surface on the front side of a portion having no carrier port 42a. In this event, the first housing 42 may be rotated 180° or moved in the Y-direction. A raising and lowering mechanism may be provided under the first housing 42 and vertically moves the first housing 42 to deviate the carry-in/out port 60a from the carrier port 42a to thereby shut the carry-in/out port 60a.

While both of the X-Y stage 210 and the rotary table 211 are provided in the first space L in the above-described embodiment, any one of the X-Y stage 210 and the rotary table 211 may be provided as long as the carry-in/out port 60a can be shut by a portion of the housing 42 or 43 by moving the housing 42 or 43.

Even when the first space L is partitioned into the spaces L1 and L2 in the two upper and lower tiers in each of which the housing and the inspection unit are provided as shown in FIG. 7, the X-Y stage 210 and the rotary table 211 are provided for each housing in each space so that the carry-in/out port 60a can be shut by a portion of the housing by moving the housing in each space.

While the partition plate 60 described in the above-described embodiment is formed with one carry-in/out port 60a for the housing, one carry-in/out port 60a may be provided for each unit in the housing and a shutter, a shutter drive portion, and a confirmation button may be provided for each carry-in/out port 60a.

While the first space L where maintenance is performed is shut off from the second space K where the wafer carrier nit 40 exists in the above embodiment, it is only required that the first space L where maintenance is performed is shut off from the remaining second space, and the second space may include a space in addition to the space where the wafer carrier unit 40 exists.

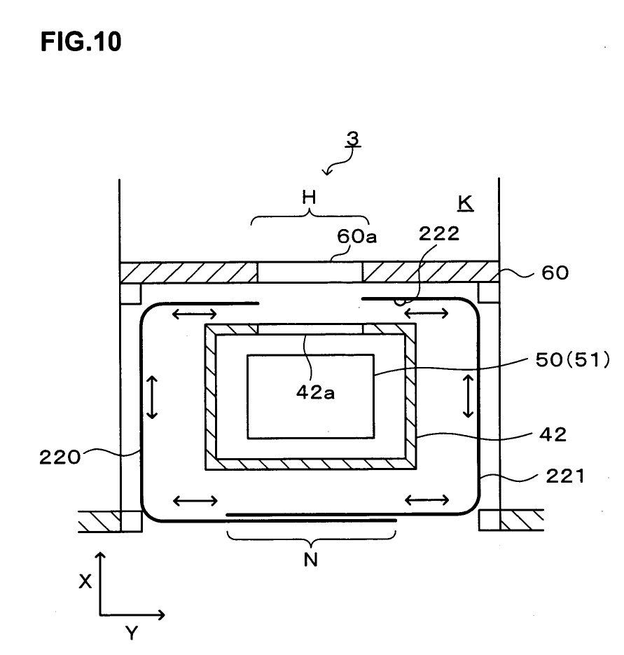

While the partition plates 60 are provided between the wafer carrier unit 40 and the inspection units 50 to 52 to shut the first spaces L off from the second space K by the shutters 61 in the above-described embodiment, sliding shutters 220 and 221 may be provided, for example, around each of the inspection units 50 to 52 as shown in FIG. 10 to open/shut a wafer carrier path H between each of the inspection units 50 to 52 and the wafer carrier unit 40, and an opening portion N formed in the side wall of the casing 1a.

The opening portion N for allowing the operator to access the first space L is formed, for example, at a position opposed to the first housing 42 of the casing 1a. On both the right and left sides (in the Y-direction) of the first housing 42, the sliding shutters 220 and 221 are arranged which pass by the first housing 42 from the opening portion N side to reach the wafer carrier path H side. The shutters 220 and 221 can slide along the periphery of the first housing 42. The shutters 220 and 221 are arranged to open right and left (in the Y-direction) on the opening portion N side. The shutters 220 and 221 cooperate with each other to move to the opening portion N side to overlap one on the other on the opening portion N side so that they can shut the opening portion N and open the wafer carrier path H on the wafer carrier unit 40 side. Further, the shutters 220 and 221 move to the wafer carrier path H side to overlap one on the other on the wafer carrier path H side so that they can open the opening potion N and shut the wafer carrier path H.

The shutters 220 and 221 are designed to shut the wafer carrier path H at least before opening the opening portion N. More specifically, the shutters 220 and 221 are formed to have a length such that when the shutters 220 and 221 in a state of shutting the opening portion N are shifted to the wafer carrier path H side, they can first shut the wafer carrier path H and then open the opening portion N.

Further, a confirmation button 222 is provided, for example, on the shutter 220, the confirmation button 222 being pressed when the shutter 220 overlaps on the shutter 221 on the wafer carrier path H side to shut the wafer carrier path H. The confirmation button 222 electrically cooperates with, for example, the interlock disabling mechanism R, so that a press of the confirmation button 222 automatically disables the interlock mechanism I. Note that the interlock mechanism I in this case is one which stops all of the motions in the casing 1a when the shutters 220 and 221 are opened to open the opening portion N. The configuration on the second housing 43 is the same as that on the first housing 42 side and therefore its explanation will be omitted.

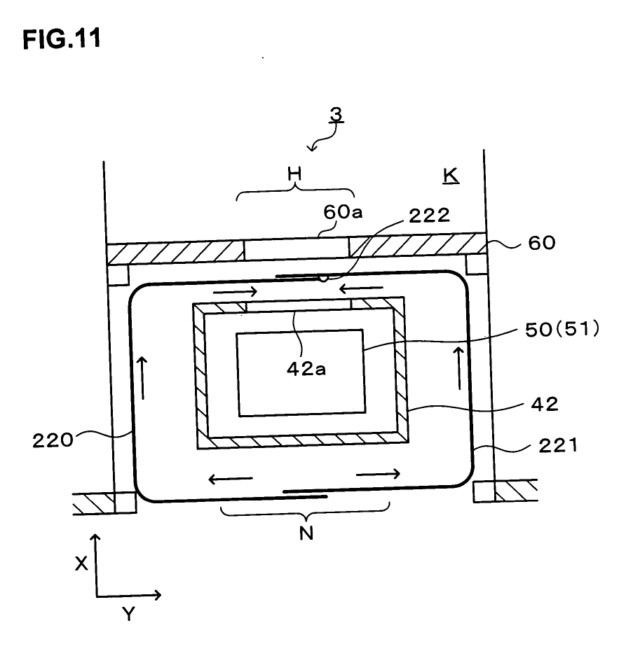

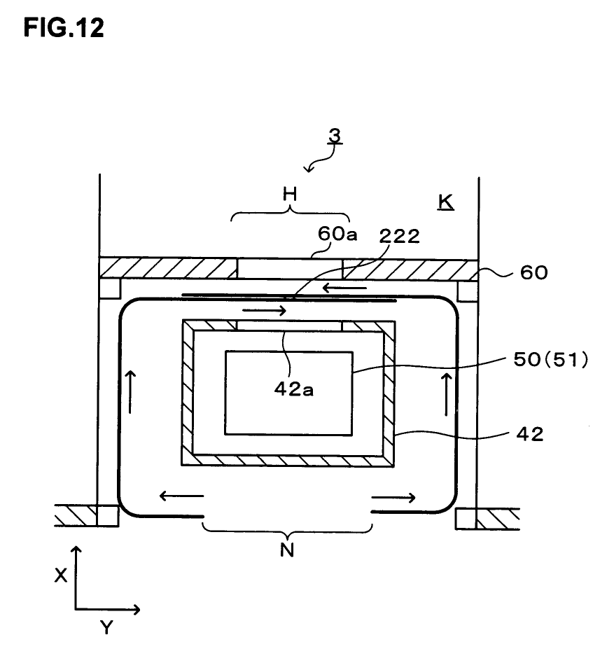

During normal operation of the coating and developing treatment apparatus 1, the opening portion N is kept shut and the wafer carrier path H is kept open as shown in FIG. 10. Therefore, the wafer carrier unit 40 can access the inspection units 50 to 52 through the wafer carrier paths H. When the operator performs maintenance of the inspection units 50 to 52, the operator opens the shutters 220 and 221 to both the right and left sides on the opening portion N side. At this time, the wafer carrier path H is shut in the state in which the shutter 220 and the shutter 221 still overlap one on the other on the opening portion N side to shut the opening portion N as shown in FIG. 11. In other words, both the opening portion N and the wafer carrier path H are temporarily shut in the process of opening the shutters 220 and 221. The confirmation button 222 is then pressed, for example, by the shutter 220 at this time to disable the interlock mechanism I. Thereafter, when the shutters 220 and 221 are further opened, the opening portion N is opened as shown in FIG. 12. After the opening portion N is opened, the operator performs maintenance of each of the inspection units 50 to 52.

Also in the above example, when the operator is allowed to access each of the inspection units 50 to 52, the wafer carrier path H is shut to shut the space where each of the inspection units 50 to 52 exists off from the space where the wafer carrier unit 40 exists, ensuring the safety of the operator. The safety standards of the apparatus can also be met. Since the interlock mechanism I becomes disabled during maintenance by the operator, it is possible to successively operate the coating and developing treatment apparatus 1 and continue the wafer processing and the wafer carriage even during the maintenance. While the shutters 220 and 221 in this example are of sliding type, they are not limited to those but may have other configurations as long as they shut the wafer carrier path H at least before the opening portion N is opened.

Although one example of the embodiment of the present invention has been described, the present invention is not limited to this example but may have various forms. While, for example, the film thickness and line width inspection unit 50, the macrodefect inspection unit 51, and the overlay inspection unit 52 are arranged in the inspection station 3 which will be subjected to maintenance in the embodiment, other inspection unit such as a film thickness measuring unit for performing only film thickness measurement of the wafer W may be located. Further, the substrate units which are subjected to maintenance are the inspection units 50 to 52 in the above embodiment, but the substrate units may be other units in the casing 1a. For example, the substrate units may be the processing and treatment units in the processing station 4. Further, the present invention is applicable not only to the coating and developing treatment apparatus 1 but also to substrate processing apparatuses such as an etching apparatus, a film forming apparatus for an insulating film or an electrode film, and a cleaning apparatus. The present invention is also applicable to substrate processing apparatuses not only for the semiconductor wafer but also for other substrates such as an FPD (flat panel display) substrate, a glass substrate for photomask, and so on.

The present invention is useful in ensuring the safety of work on the substrate processing apparatus, while restraining a decrease in operation rate of the substrate processing apparatus due to the work.

1. A substrate processing apparatus including a substrate unit capable of housing a substrate and a substrate carrier unit for carrying the substrate to the substrate unit, in a casing, comprising:
an outer wall panel detachably attached to the casing at a position opposed to said substrate unit;
a shut-off mechanism capable of shutting a first space within which said substrate unit is located off from a second space other than the first space within which said substrate carrier unit is located, in the casing, the first space being opened to the outside of the casing by detaching said outer wall panel;
a shut-off mechanism operating member for operating said shut-off mechanism to shut the first space off from the second space;
an interlock mechanism for stopping motion of the whole apparatus in the casing including said substrate carrier unit when said outer wall panel is detached; and
an interlock disabling mechanism for disabling said interlock mechanism when said shut-off mechanism shuts the first space off from the second space.

2. The substrate processing apparatus as set forth in claim 1, wherein:
a partition plate is provided between the first space and the second space;
a substrate carry-in/out port for allowing said substrate carrier unit to carry the substrate therethrough to said substrate unit is provided in the partition plate; and
said shut-off mechanism comprises a shutter for opening/shutting the substrate carry-in/out port and a shutter drive portion for driving the shutter.

3. The substrate processing apparatus as set forth in claim 1, wherein:
a partition plate is provided between the first space and the second space;
a substrate carry-in/out port for allowing said substrate carrier unit to carry the substrate therethrough to said substrate unit is provided in the partition plate;
the substrate unit is housed in a housing provided in the first space;
a substrate carrier port for allowing said substrate carrier unit to carry the substrate therethrough to said substrate unit is provided at a position opposed to the substrate carry-in/out port in the housing; and
said shut-off mechanism comprises a housing moving device capable of shutting the substrate carry-in/out port with a wall surface of the housing by moving the housing to displace the position of the substrate carrier port.

4. The substrate processing apparatus as set forth in claim 3, wherein
said housing moving device comprises a rotation device for rotating the housing.

5. The substrate processing apparatus as set forth in claim 1, wherein
said shut-off mechanism operating member is provided on said outer wall panel.

6. The substrate processing apparatus as set forth in claim 1, wherein
said shut-off mechanism operating member is capable of electrically or mechanically operating said shut-off mechanism.

7. The substrate processing apparatus as set forth in claim 1, wherein
said shut-off mechanism operating member is a switch member for operating said shut-off mechanism by a press thereof,
said switch member being electrically cooperating with said shut-off mechanism.

8. The substrate processing apparatus as set forth in claim 1, further comprising:
a shut-off confirmation member for confirming that the first space is shut off from the second space.

9. The substrate processing apparatus as set forth in claim 8, wherein
said interlock disabling mechanism disables said interlock mechanism based on confirmation by said shut-off confirmation member.

10. A substrate processing apparatus including a substrate unit capable of housing a substrate and a substrate carrier unit for carrying the substrate to the substrate unit, in a casing, comprising:
a substrate carrier path between said substrate carrier unit and said substrate unit;
an opening portion formed in a wall surface of the casing on a side opposite to said substrate carrier path across from said substrate unit;
a shutter capable of opening/shutting said substrate carrier path and said opening portion to shut said substrate carrier path at least before opening said opening portion;
an interlock mechanism for stopping motion of the whole apparatus in the casing including said substrate carrier unit when said opening portion is opened; and
an interlock disabling mechanism for disabling said interlock mechanism when said shutter shuts said substrate carrier path.

11. The substrate processing apparatus as set forth in claim 10, wherein
said shutter is located on each side of right and left of said substrate unit in a manner to surround periphery of said substrate unit from said substrate carrier path side to said opening portion side and is slidable along the periphery of said substrate unit.

12. The substrate processing apparatus as set forth in claim 11, wherein
said shutters open both to the right and left sides on said opening portion side to open said opening portion.

13. The substrate processing apparatus as set forth in claim 1, wherein
said substrate unit is an inspection unit for inspecting the substrate.

14. The substrate processing apparatus as set forth in claim 13, wherein:
a carry-in/out section for carrying the substrate into/out of the casing, an inspection section for inspecting the substrate, and a processing section for processing the substrate are provided side by side in sequence in the casing;
said inspection unit and said substrate carrier unit are provided in said inspection section; and
said substrate carrier unit in said inspection section carries the substrate between said carry-in/out section and said processing section.
